(19) United States
(12) Patent Application Publication
(10) Pub. No.: US 2007/0295981 A1
(43) Pub. Date: Dec. 27, 2007

(54) Patterned light-emitting devices

(75) Inventors: Alexei A. Erchak, Cambridge, MA (US); Michael Lim, Cambridge, MA (US); Elefterios Lidorikis, Newton, MA (US); Jo A. Venezia, Boston, MA (US); Robert F. Karlicek JR., Chelmsford, MA (US); Nikolay I. Nemchuk, North Andover, MA (US)

Correspondence Address: LUMINUS DEVICES , INC.;C/O WOLF, GREENFIELD & SACKS , P.C., 600 ATLANTIC AVENUE, BOSTON, MA, 02210-2206, US

(73) Assignee: Luminus Devices, Inc., Woburn, MA (US)

(21) Appl. No.: 11/704,892

(22) Filed: Feb. 9, 2007

Related U.S. Application Data
(63) Continuation of application No. 11/272,330, filed on Nov. 10, 2005.
(60) Provisional application No. 60/659,811, filed on Mar. 8, 2005.

(51) Int. Cl. H01L 33/00

(52) U.S. Cl. 257/98; 257/E33.023; 257/E33.068

(57) ABSTRACT

Light-emitting devices (e.g., LEDs) and methods associated with such devices are provided. The devices may include a first pattern and a second pattern which are formed at one or more interfaces of the device (e.g., the emission surface). The patterns may be positioned such that light generated by the device passes through the interfaces of the patterns when being emitted. The patterns can be defined by a series of features (e.g., vias, posts) having certain characteristics (e.g., feature size, depth, periodicity, nearest neighbor distance, etc.) which may be controlled to influence properties of the light emitted from the device, including improving extraction and/or collimation of the emitted light.

### RELATED APPLICATIONS

This application is a continuation of U.S. application Ser. No. 11/272,330, filed on Nov. 10, 2005, which claims priority under 35 U.S.C. § 119(e) to U.S. Provisional Application Ser. No. 60/659,811, filed on Mar. 8, 2005, both of which are incorporated herein by reference.

### FIELD OF INVENTION

The invention relates generally to light-emitting devices, as well as related components, systems, and methods, and more particularly to light-emitting diodes (LEDs) having patterned interfaces.

### BACKGROUND

There are a variety of semiconductor-based devices, such as LEDs, which emit light. The emitted light may be characterized in a number of ways. For example, light extraction is a measure of the amount of emitted light, and light collimation is a measure of the angular deviation of the light emitted from the emission surface. Light extraction relates to device efficiency, since any light generated by the device which is not extracted can contribute to decreased efficiency. Light collimation can be of importance if a system incorporating the LED operates more efficiently using collimated light. In many applications, it can be desirable to improve light extraction and/or collimation.

### SUMMARY OF INVENTION

The invention provides light-emitting devices, as well as related components, systems, and methods.

In one embodiment, a light-emitting device including an emitting surface is provided. The device comprises a light-generating region, a first pattern formed at an interface, and a second pattern formed at an interface. Light generated within the light-generating region and emitted through the emission surface passes through the interface of the first pattern and the interface of the second pattern.

In another embodiment, a light-emitting device including an emitting surface is provided. The device comprises a light-generating region, a first pattern formed at an interface, and a second pattern formed at an interface, wherein at least one of the first and the second patterns intersects the light-generating region.

In another embodiment, a method of forming a light-emitting device is provided. The method comprises forming a light-generating region, forming a first pattern at an interface, and forming a second pattern at an interface. The device is such that light generated within the light-generating region and emitted through the emission surface passes through the interface of the first pattern and the interface of the second pattern.

In another embodiment, a method of forming a light-emitting device is provided. The method comprises forming a light-generating region, forming a first pattern at an interface, and forming a second pattern at an interface, wherein at least one of the first and the second patterns intersects the light-generating region.

In another embodiment, a method of operating a light-emitting device is provided. The method comprises generating light in a light-generating region and transmitting light through a first pattern formed at an interface and a second pattern formed at an interface.

Other aspects, embodiments and features of the invention will become apparent from the following detailed description of the invention when considered in conjunction with the accompanying drawings. The accompanying figures are schematic and are not intended to be drawn to scale. In the figures, each identical, or substantially similar component that is illustrated in various figures is represented by a single numeral or notation. For purposes of clarity, not every component is labeled in every figure. Nor is every component of each embodiment of the invention shown where illustration is not necessary to allow those of ordinary skill in the art to understand the invention. All patent applications and patents incorporated herein by reference are incorporated by reference in their entirety. In case of conflict, the present specification, including definitions, will control.

### BRIEF DESCRIPTION OF DRAWINGS

FIG. 1a is a schematic of an LED including an emission surface patterned with a first and second pattern, wherein the second pattern contours the first pattern, in accordance with one embodiment of the invention;

FIG. 1b is a schematic of a top view of an illustrative patterned emission surface associated with the LED of FIG. 1a, in accordance with one embodiment of the invention;

FIG. 2 is schematic of an LED including a first pattern and a second pattern contouring the recessed and elevated portions of the first pattern, in accordance with one embodiment of the invention;

FIG. 3 is schematic of an LED including a first, second and third patterns, in accordance with one embodiment of the invention;

FIG. 4 is a schematic of an LED including a first pattern and a second pattern only contouring the elevated portions of the first pattern, in accordance with one embodiment of the invention;

FIGS. 5a-b are schematics of LEDs including a first pattern at a first interface and a second pattern at another interface, in accordance with some embodiments of the invention;

FIG. 6a is a schematic of an LED including a first pattern at a first interface and a second pattern at another interface, where at least one pattern does not cover the entire LED emission area, in accordance with one embodiment of the invention;

FIG. 6b is a schematic of a top view of the emission surface of the LED of FIG. 6a, in accordance with one embodiment of the invention;

FIGS. 7a-g are schematics of LEDs including all least one pattern that intersects a light-generating region of the LEDs, in accordance with some embodiments of the invention;

FIG. 8a is a graph of simulated data for light extraction efficiency of an LED as a function of pattern coverage, in accordance with one embodiment of the invention; and

FIG. 8b are schematics of LED structures used in the simulation which generated the data presented FIG. 7a.

### DETAILED DESCRIPTION

Light-emitting devices (e.g., LEDs) and methods associated with such devices are provided. The devices may include a first pattern and a second pattern which are formed on one or more interfaces of the device (e.g., the emission surface). In some embodiments, the patterns may be positioned such that light generated by the device passes through the patterns when being emitted. As described further below, the patterns can be defined by a series of features (e.g., vias, posts) having certain characteristics (e.g., feature size, depth, nearest neighbor distances) which may be controlled to influence properties of the light emitted from the device including improving extraction and/or collimation of the emitted light.

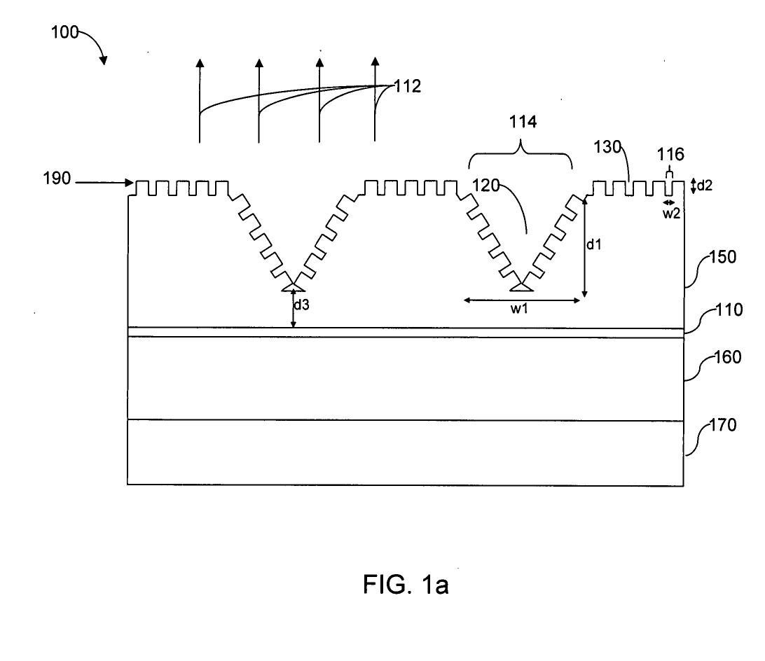

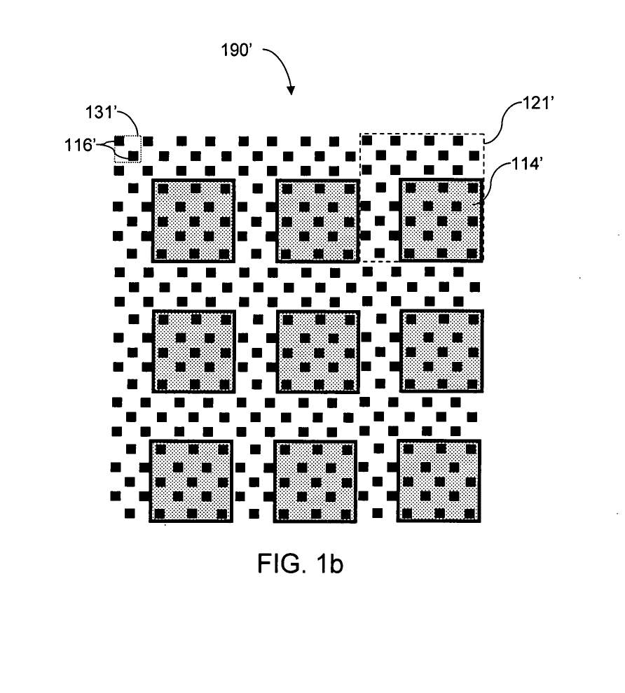

FIG. 1a illustrates an LED 100 including a light-generating region 110 (e.g., the active region of the LED) and an emission surface 190 from which light 112 is emitted. The emission surface is patterned with a first pattern 120 and a second pattern 130. The first pattern is formed of a series of vias 114 having substantially sloped sidewalls (e.g., v-shaped), while the second pattern is formed of a series of vias 116 having substantially vertical sidewalls. As shown, vias 116 of the second pattern have a cross-sectional dimension (w2) and a depth (d2) which are less than the cross-sectional dimension (w1) and depth (d1) of the vias 114 of the first pattern. As described further below, the presence of both patterns can enhance light extraction and/or collimation of the emitted light.

It should be understood that not all of the features shown in FIG. 1a need be present in all embodiments of the invention and that the illustrated elements may be otherwise positioned. Also, additional elements may be present in other embodiments. Additional embodiments are shown in the other figures and/or described further below.

When a structure (e.g., layer, region) is referred to as being “on”, “over” or “overlying” another structure, it can be directly on the structure, or an intervening structure (e.g., layer, region) also may be present. A structure that is “directly on” or “in contact with” another structure means that no intervening structure is present. It should also be understood that when a structure is referred to as being “on”, “over”, “overlying”, or “in contact with” another structure, it may cover the entire structure or a portion of the structure.

In general, as used herein, a pattern includes two or more features having similar characteristics (i.e., shape, size). Features are portions that deviate from a reference (e.g., planar) interface. The features may be vias that extend (e.g., downwards) from the reference interface (as shown in FIG. 1a), or the features may be posts that extend (e.g., upwards) from the reference interface. It should be understood that a “via” generally refers to any type of localized void that extends from a reference interface into a material layer, including voids that extend through the entire device or voids that extend through only a portion of the device. It should also be understood that a “post” generally refers to any type of localized material region that extends from a reference interface. Suitable posts may be formed of a material or structure deposited, or otherwise formed, on the reference interface. For example, the posts may be formed of a plurality of small particles that are deposited on the reference interface using colloidal deposition techniques. Also, the posts may be nanostructures (e.g., carbon nanotubes) formed on the reference interface. Alternatively or additionally, posts may be formed by over-etching a plurality of vias in the reference interface so that some etched portions join, thereby forming posts in unetched portions of the reference interface.

In general, the features of a pattern may have any suitable shape. For example, in the illustration of FIG. 1a, pattern 120 comprises vias having a v-shaped cross-section, but it should be appreciated that other type of cross-sections may also be utilized including trapezoidal profiles, rectangular profiles, arc profiles, semi-circular profiles, semi-elliptical profiles, and/or any other shape, as the invention is not limited in this regard. It should also be appreciated that the cross-sectional profile of the features may be different along different directions (i.e., different cross-sectional views of the feature). In some embodiments, a v-shaped cross-section may be preferred because the angled sidewalls can further enhance light extraction.

Patterns may be characterized as having an average feature size. As used herein, “average feature size” refers to the average cross-sectional dimension of features of a pattern. As shown in FIG. 1a, the average feature size of pattern 120 is the average of the cross-sectional dimensions of vias 114, and, the average feature size of pattern 130 is the average of the cross-sectional dimensions of vias 116. The average cross-sectional dimension (i.e., feature size) may be determined by standard techniques including microscopy techniques (e.g., SEM, AFM).

In some embodiments, including the embodiment shown in FIG. 1a, it may be preferable for the average feature size of one of the patterns to be greater than the average feature size of the other pattern. For example, the second pattern 130 may have an average feature size less than about 5 times, or less than about 2 times, the peak wavelength of the emitted light. The first pattern 120 may have an average feature size greater than about 5 times, or greater than about 10 times, the peak wavelength of the emitted light. The peak wavelength of the emitted light may depend, in part, on the specific embodiment of the device. In some embodiments, for example in which light emitted from the device is green, the second pattern 130 has an average feature size of less than 2500 nm, or less than 1000 nm. The first pattern 120 may have an average feature size of greater than 2500 nm, or greater than 5000 nm. In some embodiments, both the first and second patterns can have an average feature size that is greater than about 0.5 times the peak wavelength of the emitted light, or greater than about 250 nm for green emitted light.

It may be possible to enhance light extraction and/or collimation using two patterns having different average feature sizes, as noted above. For example, the pattern having the larger average feature size (i.e., larger pattern) may significantly contribute to enhancing light extraction; while, the pattern having the smaller average feature size (i.e., smaller pattern) may significantly contribute to enhancing light collimation. In some embodiments, the larger pattern may not significantly influence light collimation, and, in some embodiments, the smaller pattern may not significantly influence light extraction. However, it should also be appreciated that the smaller pattern can also influence light extraction, in conjunction with the larger pattern, so as to further enhance light extraction as compared to a situation when the smaller pattern was absent.

It should be understood that the invention is not limited to the average feature sizes noted above and that, in certain embodiments, the average feature size of the first pattern may be similar to the average feature size of the second pattern (e.g., when the first pattern and the second pattern are formed on different surfaces). In some embodiments, both of the patterns have an average feature size less than about 5 times, or less than about 2 times, the peak wavelength of the emitted light. In some embodiments, both of the patterns have an average feature size greater than about 5 times, or greater than about 10 times, the peak wavelength of the emitted light.

Patterns may also be characterized as having an average feature depth (for vias) or average feature height (for posts). As used herein, the “average feature depth” refers to the average distance vias of the pattern extend from the reference interface; while the “average feature height” refers to the average distance posts of the pattern extend from the reference interface. As shown in FIG. 1a, the average feature depth of pattern 120 is the average of the depths of vias 114; and, the average feature depth of pattern 130 is the average of the depths of vias 116. The average via depth (i.e., feature depth) may be determined by standard techniques including microscopy techniques (e.g., SEM, AFM).

In some embodiments, the smaller pattern may have an average feature depth (or height) smaller than the average feature depth of the larger pattern; though, in other embodiments, the smaller pattern may have an average feature depth (or height) greater than the average feature depth of the larger pattern.

Typical average feature depths (or heights) can be between about 0.1 micron and 10 microns, though the invention is not limited in this regard. For example, the small pattern may have an average feature depth of less than about 1 micron (e.g., about 0.5 microns); while, the large pattern can have an average feature depth of between about 0.5 to 5 microns (e.g., about 2 microns). In some embodiments, it may be advantageous for the feature depth of at least one of the patterns (and, in some cases, both) to be selected so that the resulting pattern is positioned close to the light-generating region. That is, the distance between at least one of the patterns and the light-generating region is relatively small in these embodiments. For example, the distance between the upper surface of the light-generating region 110 and the bottom surface of the pattern (d3 on FIG. 1a) may be less than about 2 microns (e.g., about 0.9 microns). Positioning at least one of the patterns (e.g., such as the larger pattern) near the light-generating region may enhance light extraction in certain embodiments.

Other than feature size and depth, patterns may be characterized by the spatial periodicity (e.g., in one, two, or three dimensions) or lack thereof. In particular, patterns can be periodic (e.g., having a simple repeat cell, or having a complex repeat super-cell), periodic with de-tuning, or non-periodic. Examples of complex periodic patterns include honeycomb patterns and Archimedean patterns. Examples of non-periodic patterns include quasi-crystal patterns, for example, quasi-crystal patterns having 8-fold symmetry. A non-periodic pattern can also include random surface roughness patterns having a root-mean-square (rms) roughness about equal to an average feature size which may be related to the wavelength of the emitted light, as previously described. In certain embodiments, the emitting surface is patterned with vias which can form a photonic lattice. Suitable LEDs having a photonic lattice patterned emission surface have been described in, for example, U.S. Pat. No. 6,831,302, entitled “Light Emitting Devices with Improved Extraction Efficiency,” filed on Nov. 26, 2003, which is herein incorporated by reference in its entirety.

In some embodiments, at least one pattern has a periodicity (or nearest neighbor feature distance) greater than about 20 times the peak wavelength of emitted light (e.g., about 45 times the peak wavelength (e.g., 25 microns)). In some embodiments, at least one pattern has a periodicity less than about 5 times the peak wavelength of emitted light. In some embodiments, at least one pattern has a periodicity on the order of about 2 times the average feature size. As used herein, the above-mentioned periodicity refers to the length of the unit cell along at least one dimension in a periodic pattern, but in cases where a pattern is not periodic, average nearest neighbor distance can be similarly used to characterize a pattern.

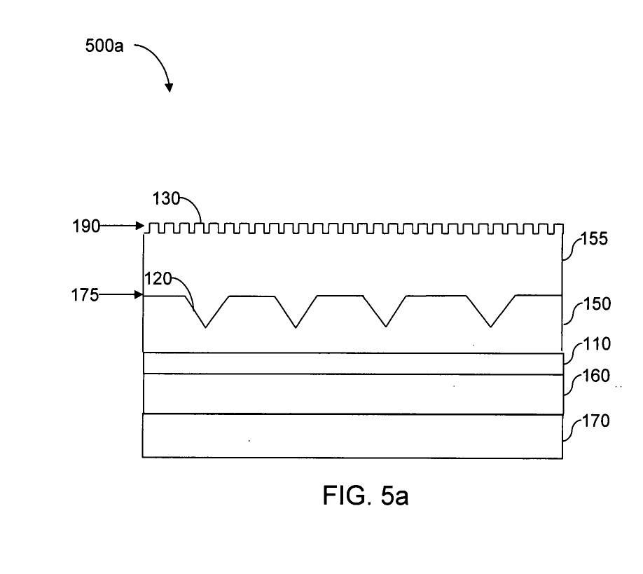

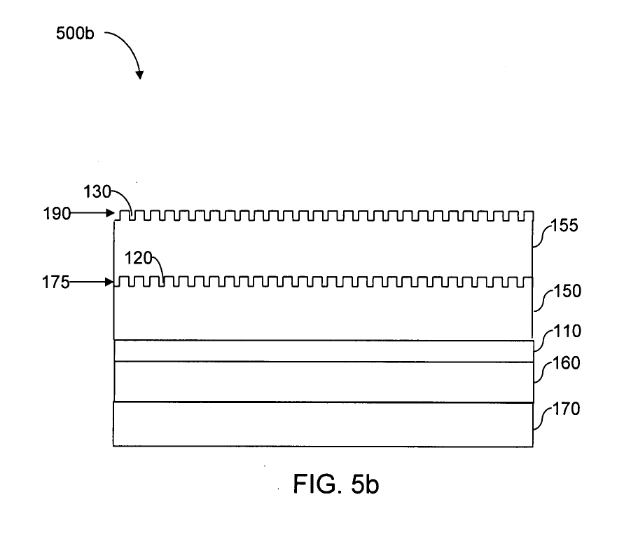

In the embodiment illustrated in FIG. 1a, the patterns are located at the emission surface of the LED and are patterned into the n-doped layer(s), but it should be understood that the pattern(s) may be present at any other interface within the LED, including interfaces between two layers within the device. For example, an interface may be formed between two layers; or, between one layer and the surroundings (e.g., atmosphere or another structure mounted on the aforementioned layer). In some embodiments, one or more patterns can be located at a buried interface (e.g., at an interface between two layers) within the LED stack, or one or more patterns can be present on any other layer disposed over the n-doped layer(s) 150. As shown in FIGS. 5a and 5b and described further below, the first pattern may be formed on one surface and the second pattern may be formed on a different surface.

In some embodiments, one (or more) patterns cover the entire area of an interface. In other embodiments, one (or more) of the patterns cover only a portion of an interface. In embodiments in which the pattern(s) cover only a portion of the interface, it may be preferable that at least a portion of the emitted light passes through both patterns.

The above-noted pattern characteristics can be selected to produce emitted light having desired properties. Pattern characteristics that can contribute significantly to light extraction include average feature size and pattern density (e.g., which can be related to the nearest neighbor distance between features, or periodicity for periodic patterns).

A pattern with suitable feature sizes on an interface (e.g., having an average feature size less than about 5 times, or less than about 2 times, the peak wavelength of the emitted light) can create a dielectric function which varies spatially along the interface. It is believed that this dielectric function variation can alter the density of radiation modes (i.e., light modes that emerge from surface) and guided modes (i.e., light modes that are confined within multi-layer stack) within the LED. This alteration in the density of radiation modes and guided modes within the LED can result in some light (that would otherwise be emitted into guided modes in the absence of the pattern) to be scattered (e.g., Bragg scattered) into modes that can leak into radiation modes.

The extraction of light (i.e., light occupying radiation modes), may be affected by the nearest neighbor distance between pattern features and by the feature size (i.e., filling factor within the pattern). It is believed that enhanced extraction efficiency can occur for an average nearest neighbor distance about equal to the wavelength of light in vacuum, although the invention is not limited in this respect. Enhanced extraction may be achieved since the nearest neighbor distance becomes significantly larger than the wavelength of the light which reduces the scattering effect because the dielectric function experienced by the light is more uniform. For periodic patterns containing one feature per unit cell, the nearest neighbor distance is the same as the periodicity. Feature size can also be represented by filling factor which refers to the percentage of area of material removed (or added) to form the pattern compared to the area of the interface. In some embodiments, the filling factor may be between about 25% and about 75% (e.g., about 50%).

Combining a pattern having a small feature size (e.g., having an average feature size less than about 5 times, or less than about 2 times, the peak wavelength of the emitted light) with a pattern having larger feature sizes (e.g., having an average feature size greater than about 5 times, or greater than about 10 times, the peak wavelength of the emitted light) can be beneficial in some cases. When one pattern (e.g., the large feature size pattern) is etched deeper into the material, large areas of the smaller feature pattern can be disposed closer to the active region of the device, while still allowing for suitable current spreading. Patterning close to the active region can facilitate light extraction out of the LED. In addition, sloped sidewalls for features of the pattern having larger feature sizes can further help reduce internal reflections at the interface.

In some embodiments, patterns may be tailored to produce a desired extraction of light at selected wavelength(s). For example, the selected wavelength(s) may be the peak wavelength(s) of the emitted light. In other cases, the selected wavelength(s) may be non-peak wavelengths. For example, the patterns may be tailored by controlling the average feature size and/or periodicity (for a periodic pattern) and/or average nearest neighbor distance (for a non-periodic pattern).

FIG. 1b illustrates a top view of an illustrative emission surface of the LED 100 shown in FIG. 1a, denoted by 190′. In this illustration, the second pattern 130 contours the first pattern 120. The first pattern in this example comprises a unit cell 121′ including a via 114′, which forms a periodic pattern. Similarly, the second pattern comprises a unit cell 131′ including vias 116′. It should be appreciated that although the patterns are periodic in this illustration, this need not necessarily always be the case. In general, one or more of the patterns may be non-periodic, periodic with detuning, or periodic, as previously described.

The LED 100 shown in FIG. 1a includes a semiconductor stack structure comprising a light-generating region 110, p-doped layer(s) 160 disposed under the light-generating region, and n-doped layer(s) 150 disposed over the light-generating region. The LED can also include a conductive layer 170 that can serve as an electrical contact to the p-doped layer(s) and also as a reflective and/or thermally conductive layer. N-metal contacts are not shown in the illustration of FIG. 1a, but are typically located on the emission surface 190 and can have any suitable size and be located at any suitable location. Suitable contacts have been described in commonly-owned U.S. Patent Application Publication No. 2005-0051785 which is incorporated herein by reference and is based on U.S. patent application Ser. No. 10/871,877 entitled “Electronic Device Contact Structures,” filed on Jun. 18, 2004.

For example, the n-metal contacts could be located in between the recessed features of pattern 120, so as to facilitate light extraction from the LED. In such cases the metal that forms the n-metal contact can be transparent to light emitted from the device. For example, the n-metal may include ITO, RuO₂, and/or any other material having suitable electrical and optical properties. It should be understood that LEDs of the invention may have a variety of other structures and are not limited to the particular structure shown in FIG. 1.

The light-generating region 110 of an LED can include one or more quantum wells surrounded by barrier layers. The quantum well structure may be defined by a semiconductor material layer (e.g., for single quantum well structures), or more than one semiconductor material layers (e.g., multiple quantum well structures), having a smaller band gap as compared to the barrier layers. Suitable semiconductor material layers for the quantum well structures include InGaN, AlGaN, GaN and combinations of these layers (e.g., alternating InGaN/GaN layers with the GaN layers serving as barrier layers), although the invention is not limited to just these materials, and the quantum well(s) may be formed of any other semiconductors.

In some embodiments, the n-doped layer(s) 150 include a silicon-doped GaN layer (e.g., having a thickness of about 2000 nm thick) and/or the p-doped layer(s) 160 include a magnesium-doped GaN layer (e.g., having a thickness of about 100 nm thick).

The conductive layer 170 may be a silver layer (e.g., having a thickness of about 100 nm) and may also serve as a reflective layer (e.g., that can reflect impinging light back towards the emission surface 190) and/or a thermally conductive layer (e.g., to aid in the extraction of heat generated in the semiconductor stack). Furthermore, although not shown, other layers may also be included in the LED; for example, an AlGaN layer may be disposed between the light-generating region and the p-doped layer(s) 160.

In general, the light-generating region 110, the n-doped layer(s) 150, and/or the p-doped layer(s) 160 of an LED can comprise one or more semiconductors materials, including III-V semiconductors (e.g., gallium arsenide, aluminum gallium arsenide, gallium aluminum phosphide, gallium phosphide, gallium arsenide phosphide, indium gallium arsenide, indium arsenide, indium phosphide, gallium nitride, indium gallium nitride, indium gallium aluminum phosphide, aluminum gallium nitride, as well as combinations and alloys thereof), II-VI semiconductors (e.g., zinc selenide, cadmium selenide, zinc cadmium selenide, zinc telluride, zinc telluride selenide, zinc sulfide, zinc sulfide selenide, as well as combinations and alloys thereof), and/or other semiconductors.

It should be understood that compositions other than those described herein may also be suitable for the layers of the LED.

Light may be generated by the LED 100 as follows. The conductive layer 170 can be held at a positive potential relative to the n-doped layer(s) 150, which causes electrical current to be injected into the LED. As the electrical current passes through the LED, electrons from n-doped layer(s) 150 can combine in the active region 110 with holes from p-doped layer(s) 160, which can cause the active region to generate light. The active region can contain a multitude of point dipole radiation sources that emit light (e.g., isotropically) within the region with a spectrum of wavelengths characteristic of the material from which the active region is formed. For InGaN/GaN quantum wells, the spectrum of wavelengths of light generated by the active region can have a peak wavelength of about 445 nanometers (nm) and a full width at half maximum (FWHM) of about 30 nm, which is perceived by human eyes as blue light.

In other embodiments, the light-generating region can generate light having a peak wavelength corresponding to ultraviolet light (e.g., having a peak wavelength of about 370-390 nm), violet light (e.g., having a peak wavelength of about 390-430 nm), blue light (e.g., having a peak wavelength of about 430-480 nm), cyan light (e.g., having a peak wavelength of about 480-500 nm), green light (e.g., having a peak wavelength of about 500 to 550 nm), yellow-green (e.g., having a peak wavelength of about 550-575 nm), yellow light (e.g., having a peak wavelength of about 575-595 nm), amber light (e.g., having a peak wavelength of about 595-605 nm), orange light (e.g., having a peak wavelength of about 605-620 nm), red light (e.g., having a peak wavelength of about 620-700 nm), and/or infrared light (e.g., having a peak wavelength of about 700-1200 nm).

Upon the generation of light in the light-generating region 110, light can proceed to be emitted through the emission surface 190, such that the light can pass through both the first and second pattern. In doing so, the extraction and/or collimation of light generated by the LED 100 can be influenced by the presence of the first and second patterns. In the illustrative embodiment of FIG. 1a, the angled sidewalls of the v-groove recessed features of pattern 120 can aid in the extraction of light generated by the LED. Furthermore, pattern 130 can also aid in the extraction of light. Moreover, the pattern 130 can also aid in the collimation of light emitted by the LED.

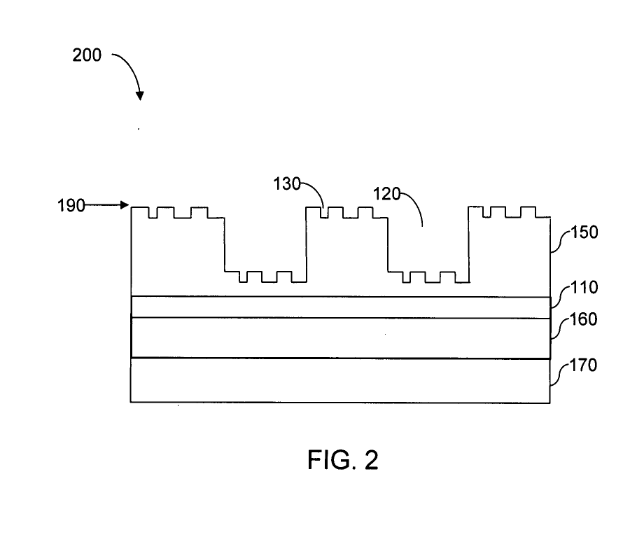

FIG. 2 illustrates another embodiment of an LED 200, similar to the embodiment of FIG. 1, though in FIG. 2, pattern 120 is formed of vias including rectangular-shaped cross-sections. The LED 200 also includes second pattern 130 that contours the first pattern 120. In the illustration of FIG. 2, the second pattern is a complex periodic pattern, but it should be appreciated that the patterns can be periodic, non-periodic, periodic with detuning, or can have any other suitable spatial distribution, as the invention is not limited in this respect.

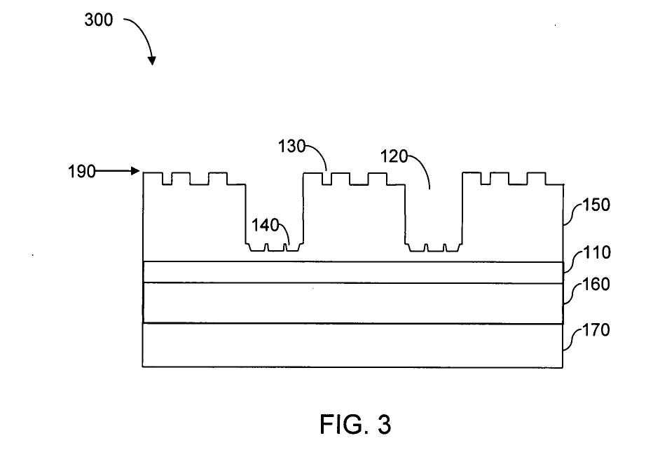

FIG. 3 illustrates another embodiment of an LED 300. In this illustrative embodiment, the first pattern 120 is the same as that of LED 200 in FIG. 2, but the second pattern 130 is only present on the elevated regions of the first pattern. In this embodiment, a third pattern 140 is present in the recessed regions of the first pattern (i.e., in the bottom of the vias). The third pattern is distinct from the second pattern and may have different features cross-sectional profiles, feature sizes, feature depths, feature nearest neighbor distances, and/or a different spatial periodicity (e.g., period, non-periodic, periodic with detuning). In the illustrative LED 300 of FIG. 3, the third pattern 140 can be such that the surface includes spikes or protrusions characterized by heights of the spikes that are significantly greater than the widths of the spikes. In some embodiments, both the second and third patterns have feature sizes less than that of the first pattern (as described above). In various embodiments, the characteristics of patterns 130 and 140 may be tailored so as to attain a desired collimation and/or extraction of light from the LED 300.

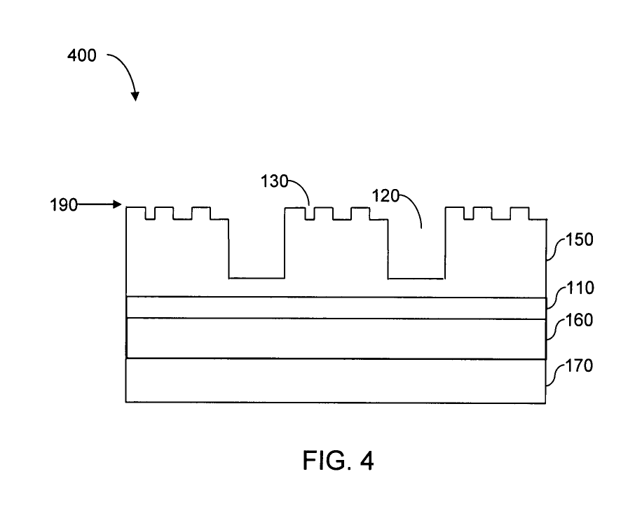

FIG. 4 illustrates another embodiment of an LED 400. In this illustrative embodiment, the first pattern 120 is the same as that of LED 200 in FIG. 2, but the second pattern 130 is only present on the elevated regions of the first pattern, and no pattern is present in the recessed regions of the first pattern. Thus, in this embodiment, the second pattern is not present across the entire area of the interface of layer 150 and the surroundings. In this illustration, the recessed regions of the first pattern are planar, but, in other embodiments, the recessed regions could have any another cross-sectional profile.

FIG. 5a illustrates another embodiment in which an LED 500a has first pattern 120 at one interface 175 and second pattern 130 at another interface (e.g., emission surface 190). For clarity, metal surface contacts (n-electrode contacts) are not shown in the illustration. In this illustrative embodiment, the semiconductor stack layers of LED 500a are similar to those described is previous embodiments, but the patterns 120 and 130 are positioned at different interfaces. In particular, the first pattern 120 is located at an interface between n-doped layer(s) 150 and a layer 155. The second pattern 130 is located at an interface between layer 155 and the surrounding atmosphere, though it should be appreciated that an additional layer may be formed on layer 155, for example, with an LED encapsulant material disposed over layer 155.

Layer 155 can be composed of any suitable material including a material having a suitable index of refraction (e.g., having an index greater than about 1.0, having an index greater than about 1.5, having an index greater than about 2.0, having an index substantially equal to that of the semiconductor material). The index of refraction can be selected so as to maximize light extraction from the LED. For example, the index of refraction can be selected to minimize back reflection at the interface between layer 155 and the n-doped layer(s) 150 and at the interface between layer 155 and any material that may be disposed over layer 155 (not shown) or the surrounding atmosphere. In some such embodiments, layer 155 is composed of one or more materials that have indices of refraction less than the index of refraction of the underlying layer 150 and/or greater than the index of refraction of a material that may be disposed over layer 155 (not shown).

In some embodiments, layer 155 is composed of a material that is thermally stable and does not degrade during LED operation. In some embodiments, layer 155 is formed of silicone, epoxy, sol gels (e.g., spin-coated sol gels) or silicon oxides, silicon nitrides, or combinations thereof. Layer 155 can also include multiple layers of materials, for example, an antireflective layer may be disposed over and/or under a transparent layer.

Alternatively or additionally, layer 155 may include a graded index structure where the index of refraction varies with depth. In one embodiment, the index of refraction of layer 155 can be graded from a high index value in the vicinity of the n-doped layer 150 to an index value at the emission surface 190 that more closely matches the index of an encapsulant material and/or the surrounding atmosphere. For example, if the emission surface of LED is exposed to an atmosphere (e.g., air) having an index of about 1.0, and the n-doped layer 150 is composed of gallium nitride having an index of about 2.3, then the index of layer 155 can be graded from about 2.3, at the interface with the n-doped layer, to a lower index near the emission surface (e.g., lower than 1.7, lower than 1.5). One material system which can be used to accomplish the aforementioned index grading is a graded silicon oxy-nitride layer, formed of silicon nitride at the interface with the n-doped layer and graded to silicon dioxide at the emission surface. In such a case, the silicon nitride has an index of about 2.0 and the silicon dioxide has an index of about 1.4. In some embodiments, the index grading of layer 155 may be achieved with multiple layers where the index is graded in discrete increments, so as to accomplish a similar effect as with a continuous grading.

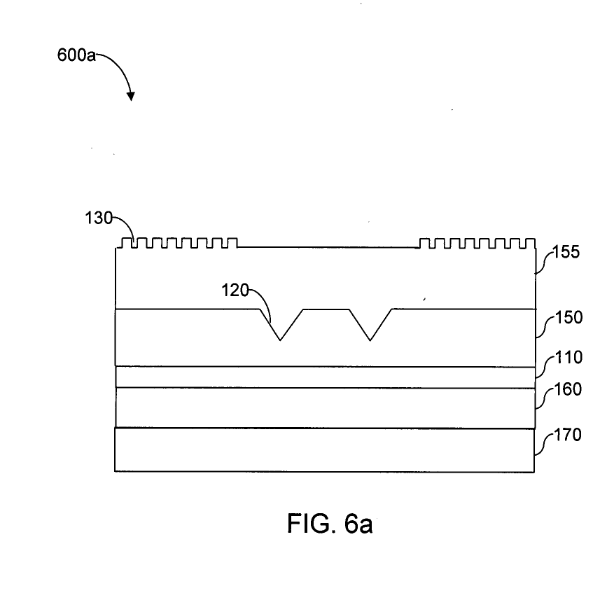

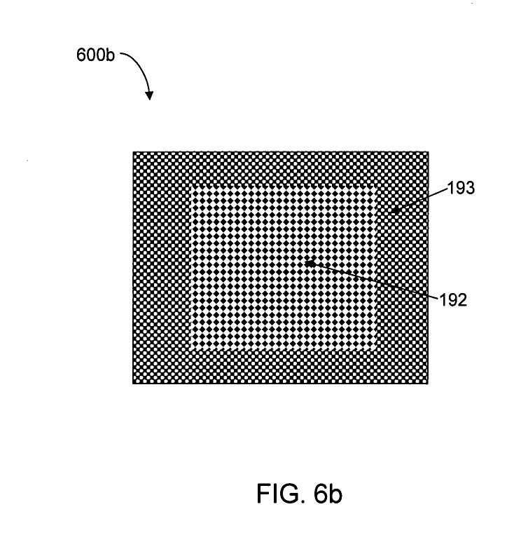

In some embodiments, when the first pattern 120 and second pattern 130 are formed at different interfaces, the first pattern 120 may have a smaller average feature size than the second pattern (as described above), or vice-versa. In some embodiments, both patterns 120 and 130 can have small average feature sizes (e.g., less than about 5 times, or less than about 2 times the peak wavelength of the emitted light). In some embodiments, patterns 120 and 130 are the same pattern, located at different interfaces. The patterns may be periodic, non-periodic, or periodic with the tuning, as previously described. In some embodiments, patterns 120 and 130 can also be off-set spatially so that features of pattern 130 does not directly overlie features of pattern 120 (e.g., as shown in FIG. 6a). In other embodiments, pattern 130 completely, or partially, overlies pattern 120.

In one embodiment, one pattern facilitates light extraction from the LED and the other pattern facilitates light collimation. For example, pattern 120 can facilitate extraction, and pattern 130 can facilitate collimation. It should also be appreciated that the patterns can also both facilitate extraction, collimation, and/or extraction and collimation.

FIG. 5b illustrates another embodiment in which an LED 500b includes two patterns at different interfaces, as in the embodiment of FIG. 5a, but in the illustration of LED 500b, both patterns 120 and 130 have similar average feature sizes. Although patterns 120 and 130 may have similar average feature sizes, the patterns need not be the same, and the patterns may have different feature depths, periodicity, nearest neighbor distances, and/or the individual features of the patterns need not be aligned to lie directly over each other. In some such embodiments, both patterns may have a small average feature size (e.g., less than about 5 times, or less than about 2 times the peak wavelength of the emitted light).

FIG. 6a illustrates another embodiment in which a LED 600a has a first pattern 120 at an interface and a second pattern 130 at another interface. In this embodiment, second pattern 130 does not overlie first pattern 120. Also, pattern 120 and pattern 130 only cover limited portions of the LED emission area. FIG. 6b illustrates a top view 600b of LED 600a, where the emission area 192 associated with the first pattern 120 does not significantly overlap with the emission area 193 of the second pattern 130.

In some embodiments, patterns 120 and 130 may located at the same interface, but can occupy different portions of the interface. An example of such an embodiment could be a structure, similar to LED 600a, where pattern 120 is located on the same interface as pattern 130.

In such embodiments, one of the patterns 120 or 130 may facilitate the extraction of light, and the other pattern may facilitate the collimation of emitted light. For example, the center pattern 120 may facilitate extraction of light, and the pattern 130 surrounding the center pattern may facilitate collimation of emitted light. Alternatively or additionally, one or both of the patterns may facilitate extraction and collimation to varying degrees.

It should be understood that the above illustrations are but some examples of LEDs having patterns at different interfaces, and different placements of patterns are possible. For example, in another embodiment, a patchwork of patterns (located at the same interface or at different interfaces) can be used to alter the far field light pattern into a desired design.

Also, it should be understood that additional patterns may be formed at additional interfaces. For example, some embodiments may include three (or four, etc.) patterns formed at three (or four, etc.) respective interfaces within the device. In some of these embodiments, all of the patterns may be identical. In other embodiments, all of the patterns may be different. In other embodiments, some of the patterns may be different and some identical. For example, identical patterns may be formed on alternating, overlying layers. That is, the first pattern may be formed at a first interface, a second pattern formed at a second interface overlying the first interface, the first pattern formed again at a third interface overlying the second interface, and the second pattern formed again at a fourth interface overlying the third interface. Such identical or alternating patterns can be arranged vertically to form a 3-dimensional lattice on the emission surface of the LED.

Stacking multiple patterns can be beneficial for use with encapsulants and/or high index coatings or layers. By patterning various interfaces (e.g., semiconductor/encapsulant, encapsulant/air), the extraction of light can be increased across each of the interfaces by accounting for the index change at the interfaces. In one embodiment, various patterns can be combined, each with a different purpose (e.g., collimation patterns, extraction patterns, polarization patterns, fresnel patterns).

Patchwork patterns (e.g., at the same or different interfaces) may be beneficial since portioning off sections of the emission surface into different patterns with different attributes can allow the light to be segmented along the emission area of the LED. For example, some portions of the emitted light may collimated, some portions may be scattered diffusely, some portions may be extracted efficiently, and/or some portions may be polarized. Such a segmentation of emitted light can facilitate tuning and/or shaping of the far-field projection of the emitted light.

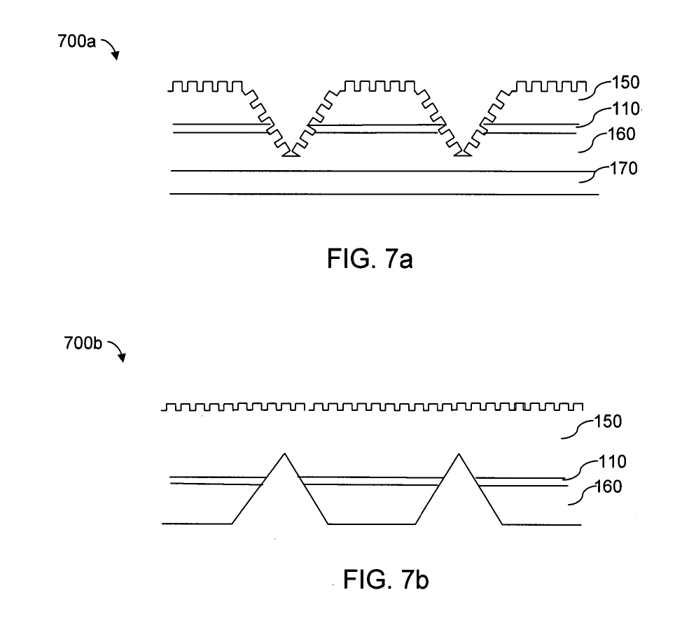

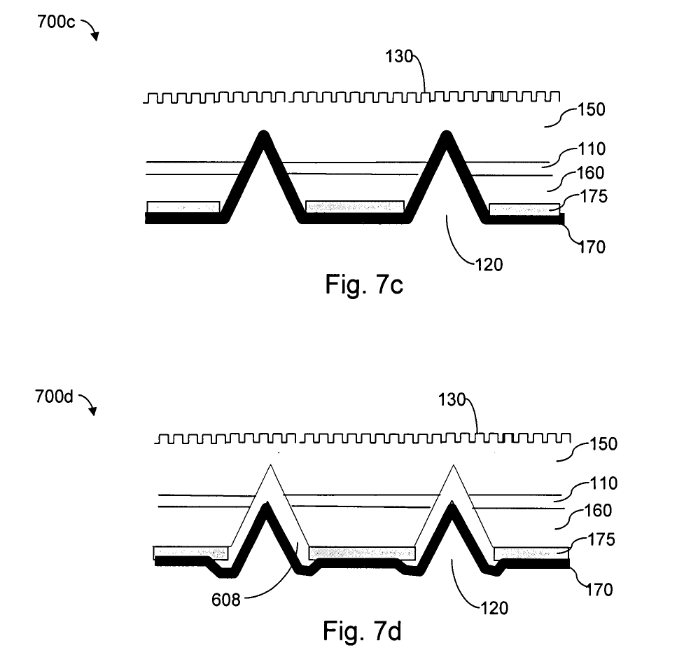

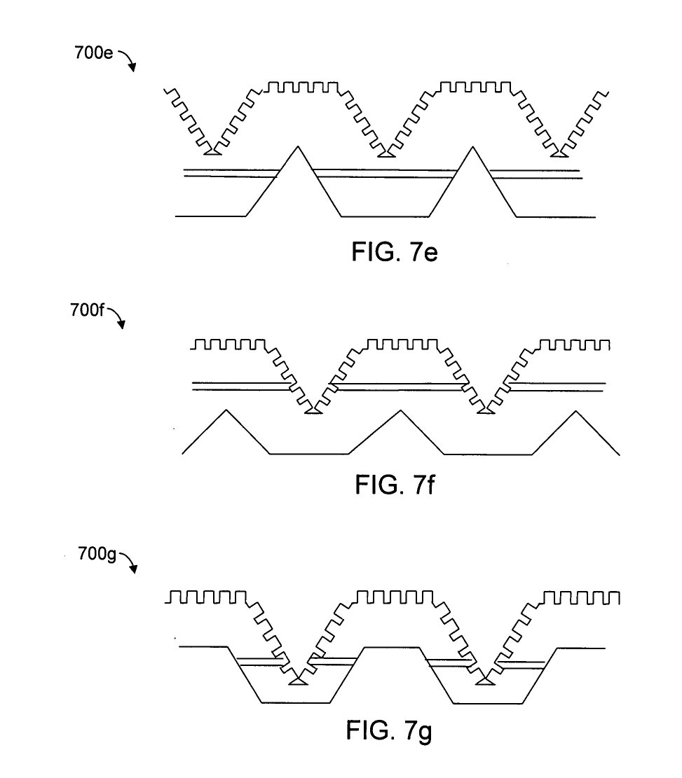

As illustrated in FIGS. 7a-g, one or more patterns may extend into the active region of the LED structure.

In some embodiments, a larger pattern (i.e., having larger feature sizes) can extend through the active region. Such embodiments may be especially beneficial for LED structures where the active region interfaces are absorptive to light traveling within the semiconductor (e.g., an AlInGaP LED). An example of one such embodiment is the LED 700a shown in FIG. 7a. As previously described, the sidewalls of the larger pattern may or may not contain smaller pattern features. In some embodiments, the larger pattern can extend near the reflective layer 170 (i.e., within a distance of 0 nm, within 10 nm, within 50 nm of the reflective layer 170). In some embodiments, the periodicity or nearest neighbor distance of the larger pattern extending through the active region is less than about 25 microns (e.g., less than about 15 microns, less than about 5 microns).

In some embodiments, a pattern may be located at a reflective backside interface of the device, opposite the emission surface. To deter absorption in certain LEDs, it may be beneficial that the backside patterning extend through the active region, as illustrated in LED 700b of FIG. 7b. In order to prevent electrical shorting via contact of a backside electrical contact (not shown) with the active region 110 of the device, an insulating layer (e.g., silicon oxide or silicon nitride) (not shown) can be disposed over the backside regions that extend into the active region. The insulating layer can also passivate the etched surface of the active region. A metal stack (not shown) can contour the entire backside etched surface, additionally making ohmic contact to portions of the backside that are not covered with an insulating film. The metal stack can contain a reflective layer. In one variation of the embodiment, a dielectric stack is used as the reflecting layer (e.g., SiO₂, ITO). In some embodiments, the emission surface can include one or more patterns that can enhance light extraction and/or collimation from the device.

FIG. 7c and FIG. 7d show illustrations of possible variations of the embodiment illustrated in FIG. 7b. FIG. 7c illustrates one such embodiment where an LED 700c includes a backside reflecting layer in combination with a surface emission pattern. The pattern 130 on the emission surface can be such that light emitted from the active region 110 can experience enhanced extraction and/or collimation. A pattern can be present on to the backside of the device, and although FIG. 7c shows a backside pattern 120 having v-groove features and feature sizes larger that the feature sizes of the emission surface pattern 130, it should be appreciated that the patterns can have any feature shapes, sizes, and/or any other defining characteristics. In the illustration of FIG. 7c, the backside pattern 120 has features that extend through the active region 110. Alternatively, the features of the backside pattern may be designed not to extend through active region 110.

Various layer(s) may be disposed over the backside pattern. FIG. 7c shows an embodiment where a p-ohmic contact 175 may be deposited prior to etching the features of backside pattern 120, and a layer 170 may be deposited after etching the features of the backside pattern. P-ohmic contact 175 can include reflective layers and/or diffusion layers. In some embodiments, layer 170 is a non-conducting reflective layer which can be removed over portions of layer 175 in order to facilitate electrical contact to the p-side of the device. In one embodiment, layer 170 is a dielectric mirror stack that serves as the non-conducting reflective layer.

In some embodiments, layer 170 is a p-metal stack which may be reflective. FIG. 7d shows an embodiment of an LED 700d where an insulating layer 608 is disposed in the etched backside pattern features between the p-metal stack 170 and the etched semiconductor surface. It should also be understood that backsides of the LEDs 700c and 700d can additionally be bonded to a supporting substrate (not shown).

It should be understood that patterns on the backside may be any of the patterns described herein. In some embodiments, both the emission surface and the backside reflective surface have patterns with average feature sizes greater than about 5 times, or greater than about 10 times, the peak wavelength of the emitted light. These patterns can be correlated and/or aligned with respect to one another or they can be randomly aligned. Examples of correlated emission surface and backside patterns are shown in the LEDs 700e, 700f, and 700g of FIG. 7e, FIG. 7f, and FIG. 7g, respectively.

In some embodiments, a preferred feature sidewall slope for the emission surface pattern extending through the active region is between about 15 and about 45 degrees (e.g., about 30 degrees). In some embodiments, a preferred feature sidewall slope for the backside pattern is between about 30 and about 60 degrees (e.g., about 45 degrees). In addition, it should be appreciated that encapsulation of any LED structure with any material having a desired index (e.g., a high index material) is possible for all embodiments discussed herein. In some embodiments, optical components (e.g., lenses, optical fibers, light collection rods) can be directly embedded into the encapsulation.

In some embodiments, the patterns may provide additional functions useful for device operation. For example, when the pattern is formed of a series of vias, the vias may function as channels through which fluid may flow, for example, to provide cooling.

Though the description and figures relate primarily to LEDs, it should be understood that the patterns described above can be used in connection with other light-emitting devices, such as lasers.

The light-emitting devices and structures described in the above embodiments can be fabricated using a combination of any suitable processing techniques. Such processes can include thin film deposition techniques, such as chemical vapor deposition, for depositing various materials, including semiconductors, insulators, and metals. Evaporation and sputtering can be utilized to deposit metals. Patterning processes, such as photo-lithography and nano-imprint techniques, may be used to form patterning masks. Etching processes, such as dry etching (e.g., reactive ion etching), and wet etching, may be used to pattern layers. Coating and spin-coating can be used to deposit some layers. Alternatively or additionally, injection molding can also be used to form some patterned layers. Wafer bonding processes may also be used to transfer structures and devices.

In some embodiments, patterns may be formed after the LED semiconductor stack is formed. Furthermore, other process steps, such as laser lift-off could be used to remove the growth substrate and transfer the LED semiconductor stack onto a submount, substrate, or support. In one embodiment, a reflective layer or layers are deposited on the semiconductor interface to be bonded to a submount. Once the desired surface of the LED is exposed, a plurality of patterns can be created so as to form the aforementioned embodiments and modifications thereof. It should be appreciated that the LED semiconductor stack need not necessarily be transferred to a submount, substrate, or support, and that the patterned LED structures described herein may be formed on an as-grown LED semiconductor stack without performing any stack transfer processes.

In some embodiments which can be used to form LEDs with a second pattern (e.g., a small feature size pattern) contouring a first pattern (e.g., a large feature size pattern), as shown in FIGS. 1a and 1b, the process can include planarizing the top layer of the LED (e.g., the n-doped layer 150) via etching, polishing, or combination thereof, such as chemical mechanical polishing (CMP). Once the surface of the LED is planarized, the first pattern (e.g., the large feature size pattern) can be formed in the surface. For example, the first pattern (e.g., the large feature size pattern) can be formed using photolithography followed by wet and/or dry etching. For example, wet etching could be used if v-groove features are desired. After this step, the surface can be patterned so as to form the second pattern (e.g., the small feature size pattern) contouring the first pattern (e.g., the large feature size pattern). The second pattern can be formed using imprint techniques, photolithography, e-beam lithography, x-ray lithography, and/or any other patterning process. In the case of imprint techniques, an imprintable polymer layer can be deposited on n-doped surface (e.g., via spin-coating), followed by mechanical pressing of a stamp with desired pattern, and an optional UV or heating step to cure imprint polymer. The stamp can then be removed, for example either by pealing the stamp off or by dissolving the stamp using a suitable solution. Since imprinting techniques can use flexible stamps that allow patterning of non-planar surfaces, such as those having a first pattern, the second pattern can be imprinted in both recessed and elevated regions of the surface. Typically, this is possible when the aspect ratio (i.e., depth to size ratio) of the pre-existing surface features are not too large. Next, the pattern in the imprint polymer layer can be transferred to the underlying surface (e.g., via a wet chemical etch or a dry etch, such as reactive ion etching), and a remaining imprint polymer can be removed. Then metal n-contact electrodes (which can include a pad section for wire-bonding to the LED package) and fingers or extensions (which can spread current over the surface of the die) are formed. The formation of the electrodes includes depositing an insulating layer which can be patterned so as to be under the contact bond pads (which can prevent current from going directly into the LED under the bond pads and can direct the current to spread through the fingers). The insulating layer can be formed of an insulating material such as silicon dioxide, silicon nitride, or combinations thereof. The insulation layer can be patterned using photolithography, and then can be followed by the deposition and patterning of n-contact electrode metal. Such a process is typically accomplished with a lift-off technique, wherein a photoresist layer is deposited (e.g., spin-coated), patterned via photolithography processes, and a contact metal stack (e.g., including various layers formed of Al, Ti, Ni, Au, W, Ag, Indium-Tin-Oxide, Cu, Rh, Pt, TiN, or combinations therefore) is deposited over the patterned photoresist. The metal stack can be deposited using evaporation, sputtering, or CVD. The photoresist mask is then removed in a solvent and subsequently lifts off any overlying metal, leaving behind patterned metal layers. Optionally, the metal stack can then be heat treated. Such a fabrication process can form LEDs similar to LED 100 illustrated in FIG. 1a.

In other embodiments, the first pattern (e.g., the large feature size pattern) may be formed after the formation of the second pattern (e.g., the small feature size pattern), for example, via the use of an isotropic etch and lithography steps. The first pattern (e.g., the large feature size pattern) can be formed, before or after, n-contact electrode patterning.

It should be understood that other processes may also be used to form the devices of the invention.

### EXAMPLE

This example illustrates how two patterns formed on the emission surface of an LED can improve the extraction of light emitted from the LED.

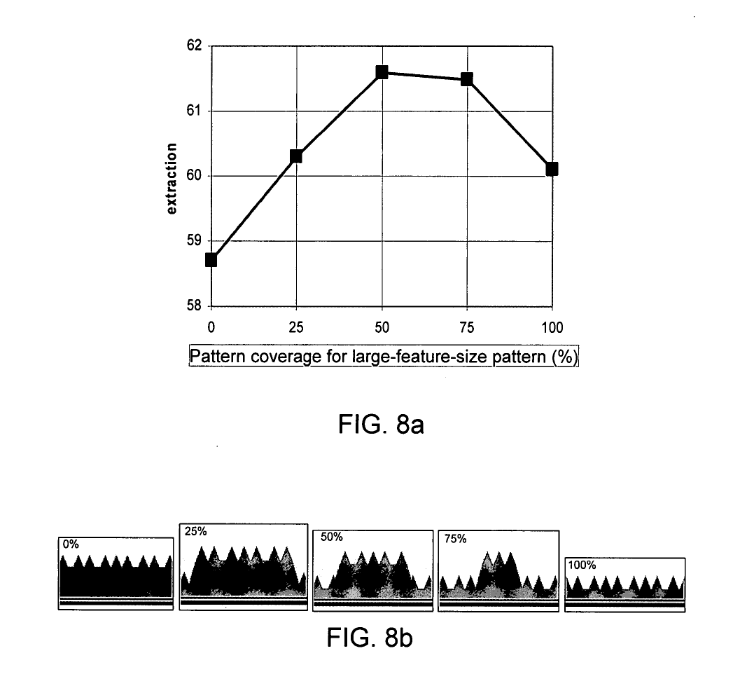

FIG. 8a illustrates simulation results for the extraction of light from an LED structure comprising an emission surface having a first pattern and a second pattern. The LED structures used in the simulation are illustrated in FIG. 8b. In each of the illustrated structures shown in FIG. 8b, the first pattern has a relatively large feature size and has varying amounts of interface area coverage in each structure (e.g., 0%, 25%, 50%, 75%, and 100% interface area coverage), and a second pattern is a pattern having smaller feature sizes on the order of the wavelength of emitted light. Furthermore, in this simulation, the feature depths of the first pattern is larger than the feature depths of the second pattern.

In the simulation results shown in the graph of FIG. 8a, the pattern coverage corresponds to the percentage of the emission surface which is covered by recessed regions of the first pattern's features. It should also be appreciated that the data in FIG. 8a are simulation results from a three-dimensional calculation and does not represent measured data. In particular, the data was calculated using a three-dimensional finite-difference time-domain (FDTD) calculation. In all simulated structures, the pattern with smaller feature sizes included spikes with a square base arranged in a quasicyrstalline pattern having 8-fold symmetry. The height of the spikes was 700 nm and the square base was 530 nm across. The spikes represent features etched into a 2250-thick n-GaN layer overlaying a multi-quantum well active region. A silver reflective layer was positioned 100 nm below the active region. The pattern with larger feature sizes was a square mesa of various dimensions (represented by pattern coverage over the unit cell). The height of the mesa was 1300 nm and the sidewall slope was taken to be 60 degrees.

The calculated data presented in FIG. 8a illustrates that the light extraction, given by a percentage of light generated by the active region, of the LED increases as the pattern coverage increases from 0%, and the extraction peaks between about 25% and less than about 90% pattern coverage. Beyond the peak, as the interface coverage area is increased, the light extraction decreases. As such, the presence of the first and second patterns on the emission surface enhances the extraction of light from the LED, and the pattern features can be selected so as to maximize the extraction.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. (canceled)

2. A device comprising:
a semiconductor stack including a light emitting layer disposed between an n-type region and a p-type region;
a photonic crystal structure formed in at least a portion of the semiconductor stack, the photonic crystal structure comprising a lattice of holes in the stack;
wherein the photonic crystal structure includes at least two different lattices.

3. The device of claim 2 wherein the light emitting layer is a III-nitride layer.

4. The device of claim 2 wherein said at least two different lattices are different lattice types.

5. The device of claim 2 wherein the at least two different lattices have different lattice constants.

6. The device of claim 2 wherein the photonic crystal structure comprises:
a first lattice of holes formed in a first region of the stack; and
a second lattice of holes formed in a second region of the stack.

7. The structure of claim 6 wherein a lattice constant of the first lattice corresponds to a local maximum in a plot of power radiated from the device vs. lattice constant.

8. The structure of claim 6 wherein a lattice constant of the second lattice corresponds to a local maximum in a plot of light extraction into a 30°. cone on a surface of the stack vs. lattice constant.

9. The structure of claim 6 wherein a lattice constant of the second lattice corresponds to a local maximum in a plot of light extraction vs. lattice constant.

10. The structure of claim 6 wherein the first and second lattices of holes are configured such that at least a portion of light generated in the first region is directed toward the second region through the semiconductor stack

11. The structure of claim 6 wherein the first and second lattices are formed on a same surface of the stack.

12. The structure of claim 6 wherein the first lattice is formed on a top surface of the stack and the second lattice is formed on a bottom surface of the stack.

13. The structure of claim 6 wherein the first region is adjacent to the second region.

14. The structure of claim 6 wherein the first region surrounds the second region.

15. The structure of claim 14 further comprising a first contact surrounding the second region.

16. The structure of claim 6 further comprising a contact, wherein the contact and the first and second lattices are configured such that the contact injects current into only one of the first and second regions.

17. The structure of claim 6 wherein the first lattice has a unit cell and the first region has a width of 5 to 20 unit cells of the first lattice.

18. The structure of claim 6 wherein the first region has a width less than about 5 microns.

19. The structure of claim 6 wherein one of the first lattice and the second lattice comprises one of a triangular, square, hexagonal, and honeycomb lattice.

20. The structure of claim 6 wherein one of the first lattice and the second lattice comprises an arrangement of holes disposed on vertices of a repeating pattern of squares and equilateral triangles.

21. The structure of claim 6 further comprising:
a third lattice of holes formed on a third region of the stack.

22. The structure of claim 21 wherein the third region surrounds the first and second regions.

23. The structure of claim 21 wherein the third lattice is configured to reflect into the semiconductor stack light emitted in one of the first region and the second region.

24. The structure of claim 21 wherein the third region is disposed between the first region and the second region and the third lattice of holes is configured to couple light from the first region to the second region.

25. The structure of claim 6 wherein dielectric material fills the holes in the first lattice of holes and the second lattice of holes, wherein the at least two different lattices have different dielectric constants filling the holes.

26. The structure of claim 6 wherein a dielectric constant of the first region is different from a dielectric constant of the second region.

27. The structure of claim 2 wherein the at least two different lattices have different hole diameters.

28. The structure of claim 2 wherein the at least two different lattices have different hole depths.

29. The structure of claim 2 further comprising a metal web overlying the stack.

30. The structure of claim 29 wherein the metal web comprises:
a plurality of major traces;
and a plurality of minor traces, wherein:
the major traces have a width of 10-20 μm;
the minor traces have a width of 1-5 μm; and
the major traces are spaced between 20 and 250 μm apart.

31. A device comprising:
a semiconductor stack including a light emitting layer disposed between an n-type region and a p-type region;
a photonic crystal structure formed in at least a portion of the semiconductor stack, the photonic crystal structure comprising a pattern of holes in the stack;
wherein the photonic crystal structure includes at least two different patterns.

31. A device comprising:
a semiconductor stack including a light emitting layer disposed between an n-type region and a p-type region;
a structure formed in at least a portion of the semiconductor stack, the structure comprising a pattern of holes in the stack;
wherein the structure includes at least two different patterns.
